(19) United States
(12) Patent Application Publication
(10) Pub. No.: US 2007/0154820 A1
(43) Pub. Date: Jul. 5, 2007

(54) Photosensitive resin composition and black matrix using the same

(76) Inventors: Hyun Jung Kang, Seoul (KR); Choun Woo Lee, Suwon-Si (KR); Hee Young Oh, Seoul (KR); Cheon Seok Lee, Seongnam-Si (KR)

Correspondence Address: KNOBBE MARTENS OLSON & BEAR LLP, 2040 MAIN STREET, FOURTEENTH FLOOR, IRVINE, CA, 92614, US

(21) Appl. No.: 11/511,626

(22) Filed: Aug. 28, 2006

(30) Foreign Application Priority Data
Dec. 30, 2005 (KR) 10-2005-0134886

(51) Int. Cl. G03F 1/00

(52) U.S. Cl. 430/7

(57) ABSTRACT

A photosensitive resin composition suitable for the production of a light-shielding black matrix for use in a liquid crystal display is disclosed. The photosensitive resin composition includes a cardo binder resin and a carboxyl group-containing polyfunctional monomer and exhibits superior physical properties, such as heat resistance, chemical resistance, development margin, developability and adhesive properties. Further disclosed is a black matrix produced using the photosensitive resin composition. The black matrix has superior physical properties, including heat resistance, chemical resistance, development margin and adhesive properties. Particularly, since the black matrix has excellent developability with an alkaline solution, it contains no undissolved material of the composition in radiation-unexposed portions.

### CROSS-REFERENCE TO RELATED APPLICATION

This application claims priority to and the benefit of Korean Patent Application No. 10-2005-0134886, filed on Dec. 30, 2005, the disclosure of which is incorporated herein by reference in its entirety.

### BACKGROUND OF THE INVENTION

1. Field

The present invention relates to a photosensitive resin composition for a light-shielding black matrix for use in display devices.

2. Description of the Related Technology

Cathode ray tubes (or Braun tubes) have been widely used as electronic displays for use in office automation devices, portable small television sets, viewfinders for video cameras, and other electronic devices. In recent years, cathode ray tubes have been replaced with liquid crystal displays (LCDs), plasma display panels (PDPs), vacuum fluorescent displays (VFDs) and other displays. Considerable research efforts have been directed towards the development of these displays.

Liquid crystal displays (LCDs) have drawn attention for their light weight, small thickness, low price, low driving power consumption and excellent connectivity to integrated circuits. Based on these advantages, liquid crystal displays have been increasingly used in a wide variety of applications, including displays of laptop and pocket computers, and image displays of color TV sets for vehicles. Such liquid crystal displays typically include a lower substrate, an active circuit portion, and an upper substrate. The lower substrate includes a black matrix, color filters and indium-tin oxide (ITO) pixel electrodes formed thereon. The active circuit portion includes a liquid crystal layer, thin film transistors and a capacitor layer. The upper substrate includes ITO pixel electrodes formed thereon.

A color filter substrate for a liquid crystal display includes a plastic or glass substrate, a black matrix formed on the substrate, a color layer formed on the black matrix, an overcoat formed on the color layer, and a transparent conductive ITO layer. The color layer includes red/green/blue color filters alternating with one another. The overcoat may have a thickness of about 1 to about 3 μm, and may be formed of polyimide, polyacrylate or polyurethane. The overcoat protects the underlying color filters and maintains surface smoothness. The transparent conductive ITO layer is formed on top of the overcoat, and is applied with a voltage to drive the liquid crystal.

The black matrix blocks light which passes through areas other than the transparent pixel electrodes of the substrate. By blocking the light, the black matrix improves the contrast of the LCD. The red/green/blue color layer allows light with a particular wavelength to pass therethrough so as to produce colors. The transparent conductive film layer serves as a common electrode for applying an electric field to the liquid crystal.

The black matrix of the color filter substrate may include chromium or a resin. A black matrix including chromium is advantageous in terms of good light-shielding performance and superior environmental and chemical resistance, but has the following problems: i) the production procedure is complicated; ii) since the production apparatuses are highly priced, an increase in production costs is incurred; and iii) since the reflectance of the black matrix is high, an additional treatment process for total reflection is necessitated.

Color filter substrates may be made by dyeing, printing, pigment dispersion, electrodeposition, and other methods. Of these, pigment dispersion methods are commonly employed to produce black matrices.

According to the pigment dispersion methods, color filters are produced by coating a photosensitive composition comprising a colorant on a transparent substrate on which a black matrix is formed; exposing the coated substrate to light to form a desired pattern; removing unexposed portions using a solvent; heat-curing the resulting substrate; and repeating the procedure. Such pigment dispersion methods have advantages that they improve the heat resistance and durability of color filters, which are the most important physical properties required in color filters. In addition, the method can provide a uniform film thickness. Therefore, pigment dispersion methods are predominantly employed for the production of black matrices.

Black matrices may be produced by a composition including the following two components: i) a polymeric compound, i.e. a binder resin, that acts as a skeleton and enables the maintenance of a uniform thickness; and ii) a photopolymerizable monomer that is polymerized upon exposure to light. In addition to these components, the composition may further include a pigment, a polymerization initiator, an epoxy resin, a solvent, and other additives.

Various binder resins suitable for pigment dispersion methods have been proposed, for example, polyimide resins (Japanese Patent Laid-open No. Sho 60-237403), photosensitive resins comprising an acrylic polymer and an azide compound (Japanese Patent Laid-open Nos. Hei 1-200353, Hei 4-7373, and Hei 4-91173), photosensitive resins comprising an acrylic polymer (Korean Patent Appln. Nos. 93-20127 and 95-3135), a radical-polymerizable photosensitive resin comprising an acrylate monomer, an organic polymer binder and a photopolymerization initiator (Japanese Patent Laid-open No. Hei 1-152449), and photosensitive resins comprising a phenolic resin, a crosslinking agent with an N-methylol structure, and a photoacid generator (Japanese Patent Laid-open No. Hei 4-163552 and Korean Patent No. 92-5780).

Although photosensitive polyimide and phenolic resins as binder resins for pigment dispersion are highly heat-resistant, they have drawbacks of low sensitivity and development with organic solvents. Conventional systems using an azide compound as a photosensitive agent have problems of low sensitivity and poor heat resistance, and are affected by oxygen upon exposure. To overcome such problems, some methods have been attempted, for example, installation of an oxygen-blocking film and exposure to an inert gas. However, these methods involve complex processes and require the use of expensive apparatuses.

Photosensitive resins which use acids formed by exposure to form patterns are highly sensitive without being affected by oxygen upon exposure. However, heating of the photosensitive resins is further needed during exposure and development. At this time, heating time has a great influence on the pattern formation of the photosensitive resins, which makes the process maintenance difficult.

To solve these problems, methods for the production of color filters by using a cardo binder resin are described in Japanese Patent Laid-open Nos. Hei 7-64281, Hei 7-64282, Hei 8-278630, Hei 6-1938 and Hei 5-339356, and Korean Patent Laid-open No. 95-7002313. Generally, cardo resins are highly sensitive without being affected by oxygen, and exhibit superior resistance to heat, shrinkage and chemicals.

However, photosensitive resin compositions used in the methods tend to have poor developability and weak adhesion to glass substrates due to their bulky molecular structure and high pigment content. Particularly, since the photosensitive resin compositions require the use of a larger amount of a black pigment to satisfy high optical density required in black matrices, in contrast to other colored photosensitive resin compositions, they have serious problems in developability and adhesion to glass substrates.

When a photosensitive resin composition laminated on a substrate is irradiated with actinic rays so as to form a desired pattern on a color filter, it responds to light. Unexposed portions are removed using a developing solution. Developing solutions are divided into two types, i.e. organic solvent and alkali development types. Alkali development-type developing solutions are non-toxic to the environment, whereas organic solvent-type developing solutions cause air pollution and are toxic to humans.

Thus, there is a need to provide a photosensitive resin composition suitable for a black matrix that has improved developability and good adhesive properties without causing environmental problems despite high content of a black pigment. The embodiments described below address these needs and provide other advantages as well.

The discussion in this section is to provide information about related technology and does not constitute an admission of prior art.

### SUMMARY

One aspect of the invention provides a composition for making a black strip or matrix in a display device. The composition comprises a black pigment; and a polymerizable compound represented by Formula 1:

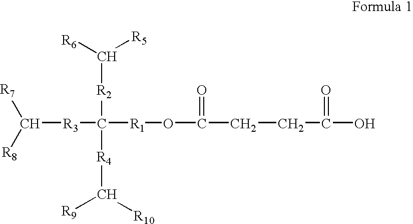

wherein R1 is a saturated or unsaturated, substituted or unsubstituted, C₁-C₂₀ alkyl, the substituted C₁-C₂₀ alkyl being substituted with one or more halogens; wherein each of R2, R3, and R4 is independently no atom or a saturated or unsaturated, substituted or unsubstituted C₁-C₁₉ alkyl, the substituted C₁-C₁₉ alkyl being substituted with one or more halogens; wherein each of R5-R10 is independently hydrogen or a substituent group represented by Formula 1-1:

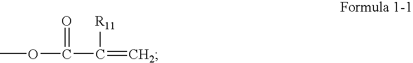

wherein R11 is hydrogen or methyl; and wherein the total number of the substituent groups represented by Formula 1-1 in the polymerizable compound is between 3 and 6.

The polymerizable compound may comprise 3 to 6 of reactive ethylenyl groups which are cross-linkable to another polymerizable compound or polymer. Each of R2, R3, and R4 may be independently straight alkyl.

The polymerizable compound may be represented by Formula 4 or Formula 5:

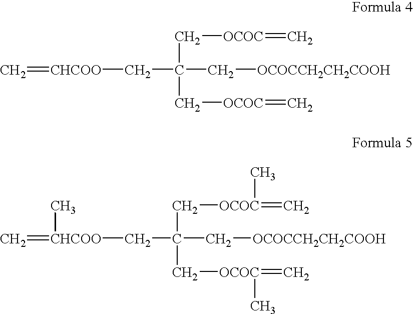

The composition may further comprise a cardo resin. The cardo resin may comprise a polymer of at least two or more selected from the group consisting of compounds represented by Formulas 2-1, 2-2 and 2-3:

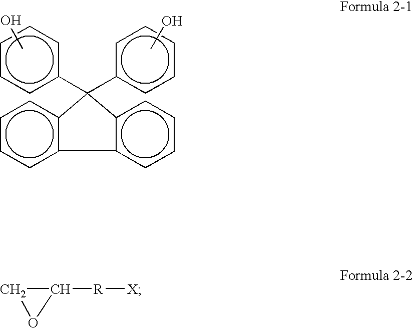

and

CH₂═CRCOOH Formula 2-3

wherein R is hydrogen, substituted or unsubstituted C₁-C10 alkyl, substituted or unsubstituted allyl, substituted or unsubstituted phenyl, substituted or unsubstituted benzyl, or substituted or unsubstituted C1-C8 epoxy, and wherein X is halogen.

The composition may further comprise a photo-polymerizable acrylic monomer. The polymerizable compound may be in an amount from about 25 to about 50 parts by weight based on 100 parts by weight of the acrylic monomer. The composition may further comprise a photo-polymerization initiator. The composition may be in a form of film. The film may comprise a form of matrix or stripe.

Another aspect of the invention provides an electronic device comprising a display comprising a black layer, the black layer comprising: a black pigment; and a polymer of a polymerizable compound represented by Formula 1:

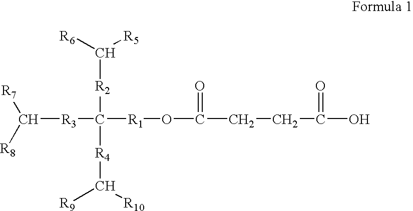

wherein R1 is a saturated or unsaturated, substituted or unsubstituted, C1-C20 alkyl, the substituted C1-C20 alkyl being substituted with one or more halogens; wherein each of R2, R3, and R4 is independently no atom or a saturated or unsaturated, substituted or unsubstituted C1-C19 alkyl, the substituted C1-C19 alkyl being substituted with one or more halogens; wherein each of R5-R10 is independently hydrogen or a substituent group represented by Formula 1-1:

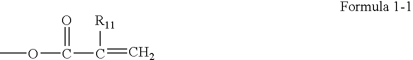

wherein R11 is hydrogen or methyl; and wherein the total number of the substituent groups represented by Formula 1-1 in the polymerizable compound is between 3 and 6.

The polymerizable compound may be represented by Formula 4 or Formula 5:

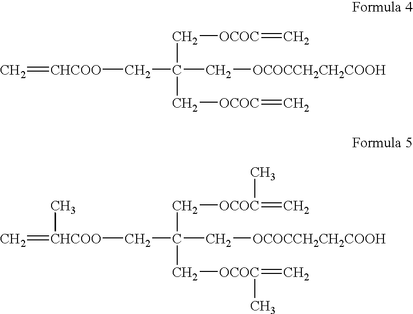

The black layer may further comprise a cardo resin. At least a portion of the polymer of the polymerizable compound may be cross-linked to the cardo resin. The display device may comprise a substantially transparent substrate, a color layer, and a black matrix interposed between the substrate and the color layer, and the black matrix may comprise the black layer. The display device may comprise a liquid crystal display (LCD) device.

Another aspect of the invention provides a method of making an electronic device comprising a display. The method comprises: forming a layer of the composition described above on a partially fabricated electronic device; selectively irradiating light onto the layer of the composition; and treating the layer of the composition with a developing solution. The light may comprise UV or X-ray.

Another aspect of the invention provides an electronic device made by the method described above.

Another aspect of the invention provides an alkali development-type photosensitive resin composition for the production of a black matrix comprising a carboxyl group-containing polyfunctional monomer so that the developability, adhesive properties and development margin are improved despite high content of a black pigment added for high optical density.

Another aspect of the invention provides a photosensitive resin composition comprising at least one carboxyl group-containing polyfunctional monomer selected from the group consisting of: esterification products of free hydroxyl group-containing poly(meth)acrylates, which are partially esterified products of trihydric or higher polyhydric alcohols with (meth)acrylic acids, and dicarboxylates; and esterification products of trivalent or higher polyvalent carboxylic acids and monohydroxyalkyl(meth)acrylates. The composition may comprise a cardo binder resin, a photopolymerizable acrylic monomer, a photopolymerization initiator, a black pigment and a solvent, in addition to the carboxyl group-containing polyfunctional monomer.

Another aspect of the invention provides a method for producing a light-shielding black matrix for use in a liquid crystal display by using the composition. Another aspect of the invention provides a light-shielding black matrix for use in a liquid crystal display using the composition. Another aspect of the invention provides a display device comprising the light-shielding black matrix. The composition may further comprise a predetermined amount of at least one additive selected from surfactants, antioxidants, stabilizers, and other additives so long as the physical properties of the composition are not impaired.

### DETAILED DESCRIPTION

Hereinafter, embodiments of the invention will be explained below in detail.

In one embodiment, a photosensitive resin composition for the production of a black matrix is provided. The composition includes a polymerizable compound, a binder resin, a photopolymerizable acrylic monomer, a photopolymerazation initiator, a black pigment, and a solvent.

The polymerizable compound includes a compound represented by Formula 1:

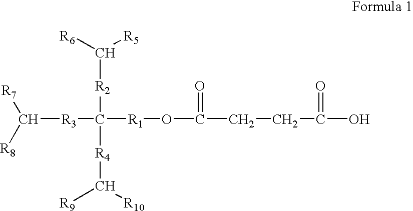

In Formula 1, R1 is a saturated or unsaturated, substituted or unsubstituted, C₁-C₂₀ alkyl. The substituted C₁-C₂₀ alkyl may be substituted with one or more halogens. Each of R2, R3, and R4 is independently no atom or a saturated or unsaturated, substituted or unsubstituted C₁-C₁₉ alkyl. The substituted C₁-C₁₉ alkyl may be substituted with one or more halogens. Each of R5-R10 is independently hydrogen or a substituent group represented by Formula 1-1:

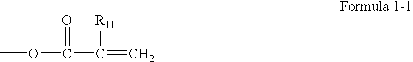

### In Formula 1-1, R11 is hydrogen or methyl.

In Formula 1, the total number of the substituent groups represented by Formula 1-1 in the polymerizable compound is between 3 and 6. Examples of the polymerizable compound will be described later. The polymerizable compound serves to achieve superior developability and good adhesive properties while attaining high optical density.

The binder resin may include a cardo resin. The cardo resin is used as a binder resin to improve the heat resistance, chemical resistance and development margin of the composition. The cardo resin may have a molecular weight of about 1,000 to about 20,000. The cardo resin may be prepared by copolymerization of monomers A, B and C represented by the following formulae 1 to 3, respectively, in a molar ratio of about 1: about 2-4: about 2-8:

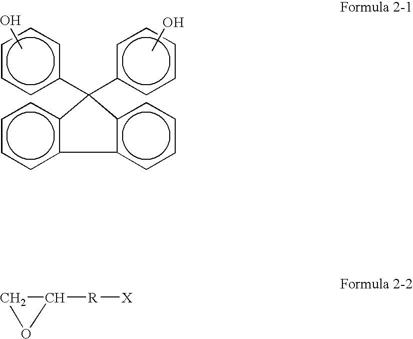

wherein R is a hydrogen atom, C₁-C₁₀ alkyl, allyl, phenyl, benzyl or C-C8 epoxy, and X is a halogen atom; and

CH₂═CRCOOH Formula 2-3

wherein R is a hydrogen atom, C₁-C₁₀ alkyl, allyl, phenyl, benzyl or C₁-C₈ epoxy, and X is a halogen atom. The binder resin may be in an amount from about 1 to about 40 parts by weight, based on 100 parts by weight of the resin composition.

In certain embodiments, the binder resin is treated with an acid anhydride to make it alkali-soluble. The acid anhydride used in the embodiments has a structure represented by the following Formula 3:

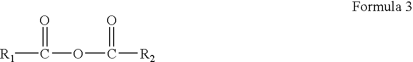

wherein R1 and R2 are each independently a hydrogen atom, C₁-C₁₀ alkyl, allyl, phenyl, benzyl or C₁-C₈ epoxy, and X is a halogen atom.

In one embodiment, the photopolymerizable acrylic monomer may be a monomer commonly used to prepare photosensitive resin compositions. Examples of the photopolymerizable acrylic monomer include, but are not limited to, ethylene glycol diacrylate, triethylene glycol diacrylate, 1,4-butanediol diacrylate, 1,6-hexanediol diacrylate, neopentyl glycol diacrylate, pentaerythritol diacrylate, pentaerythritol triacrylate, dipentaerythritol diacrylate, dipentaerythritol triacrylate, dipentaerythritol pentaacrylate, pentaerythritol hexaacrylate, bisphenol A diacrylate, trimethylolpropane triacrylate, novolac epoxy acrylate, ethylene glycol dimethacrylate, diethylene glycol dimethacrylate, triethylene glycol dimethacrylate, propylene glycol dimethacrylate, 1,4-butanediol dimethacrylate, and 1,6-hexanediol dimethacrylate. The photopolymerizable acrylic monomer may be in an amount from about 1 to about 20 parts by weight, based on 100 parts by weight of the composition.

The photopolymerization initiator may be a photopolymerization initiator commonly used to prepare photosensitive resin compositions. Examples of photopolymerization initiators include, but are not limited to, acetophenone, benzophenone, thioxanthone, benzoin, and triazine compounds. The photopolymerization initiator may be in an amount from about 0.1 to about 10 parts by weight, based on 100 parts by weight of the composition.

Examples of acetophenone compounds suitable for the use as photopolymerization initiators include 2,2′-diethoxyacetophenone, 2,2′-dibutoxyacetophenone, 2-hydroxy-2-methylpropiophenone, p-t-butyltrichloroacetophenone, p-t-butyldichloroacetophenone, benzophenone, 4-chloroacetophenone, 4,4′-dimethylaminobenzophenone, 4,4′-dichlorobenzophenone, 3,3′-dimethyl-2-methoxybenzophenone, 2,2′-dichloro-4-phenoxyacetophenone, 2-methyl-1-(4-(methylthio)phenyl)-2-morpholinopropan-1-one, and 2-benzyl-2-dimethylamino-1-(4-morpholinophenyl)-butan-1-one.

Examples of suitable benzophenone compounds include benzophenone, benzoyl benzoic acid, methyl benzoyl benzoate, 4-phenyl benzophenone, hydroxybenzophenone, acrylated benzophenone, 4,4′-bis(dimethylamino)benzophenone, and 4,4′-bis(diethylamino)benzophenone.

Examples of suitable thioxanthone compounds include thioxanthone, 2-chlorothioxanthone, 2-methylthioxanthone, isopropylthioxanthone, 2,4-diethylthioxanthone, 2,4-diisopropylthioxanthone, and 2-chlorothioxanthone.

Examples of suitable benzoin compounds include benzoin, benzoin methyl ether, benzoin ethyl ether, benzoin isopropyl ether, benzoin isobutyl ether, and benzyl dimethyl ketal.

Examples of suitable triazine compounds include 2,4,6-trichloro-s-triazine, 2-phenyl-4,6-bis(trichloromethyl)-s-triazine, 2-(3′,4′-dimethoxystyryl)-4,6-bis(trichloromethyl)-s-triazine 2-(4′-methoxynaphthyl)-4,6-bis(trichloromethyl)-s-triazine, 2-(p-methoxyphenyl)-4,6-bis(trichloromethyl)-s-triazine, 2-(p-styryl)-4,6-bis(trichloromethyl)-s-triazine, 2-biphenyl-4,6-bis(trichloromethyl)-s-triazine, bis(trichloro methyl)-6-styryl-s-triazine, 2-(naphtho-1-yl)-4,6-bis(trichloromethyl)-s-triazine, 2-(4-methoxynaphtho-1-yl)-4,6-bis(trichloromethyl)-s-triazine, 2-4-trichloromethyl(piperonyl)-6-triazine, and 2-4-trichloromethyl(4′-methoxystyryl)-6-triazine.

In other embodiments, carbazole, diketone, sulfonium borate, diazo, biimidazole compounds can be used as a photopolymerization initiator.

Examples of the black pigment include, but are not limited to, aniline black, perylene black, titanium black, and carbon black. As color correction agents, fused polycyclic pigments, such as anthraquinone and perylene pigments, and organic pigments, such as phthalocyanine and azo pigments, can be additionally used. The black pigment may be in an amount from about 5 to about 40 parts by weight, based on 100 parts by weight of the photosensitive resin composition.

The polymerizable compound described above may be a carboxyl group-containing polyfunctional monomer. The monomer may be prepared by esterification of a free hydroxyl group-containing poly(meth)acrylate. The monomer may be a partially esterified product of a trihydric or higher polyhydric alcohol with (meth)acrylic acids, with dicarboxylates; or esterification product of a trivalent or higher polyvalent carboxylic acid and monohydroxyalkyl(meth)acrylates. The monomer contains two or more polymerizable ethylenically unsaturated bonds.

Examples of the carboxyl group-containing polyfunctional monomer may include: free carboxylic group-containing mono-esterified products of monohydroxyl oligoacrylates or monohydroxyl oligomethacrylates, such as trimethylolpropane diacrylate, trimethylolpropane dimethacrylate, pentaerythritol triacrylate, pentaerythritol trimethacrylate, dipentaerythritol triacrylate and dipentaerythritol trimethacrylate, with dicarboxylic acids, such as malonic acid, succinic acid, glutamic acid and terephthalic acid; and free carboxylic group-containing oligo-esterified products of tricarboxylic acids, such as propane-1,2,3-tricarboxylic acid (tricarballylic acid), butane-1,2,4-tricarboxylic acid, benzene-1,2,3-tricarboxylic acid, benzene-1,3,4-tricarboxylic acid and benzene-1,2,5-tricarboxylic acid, with monohydroxyl monoacrylates or monohydroxyl monomethacrylate, such as 2-methacrylates.

One of esterification products of the free hydroxyl group-containing poly(meth)acrylates, which are partially esterified products of trihydric or higher polyhydric alcohols with (meth)acrylic acids, and dicarboxylates is represented by Formula 4 below:

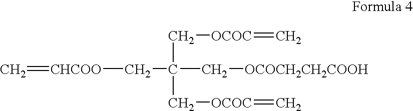

One example of esterification products of trivalent or higher polyvalent carboxylic acids and monohydroxyalkyl(meth)acrylates is represented by Formula 5 below:

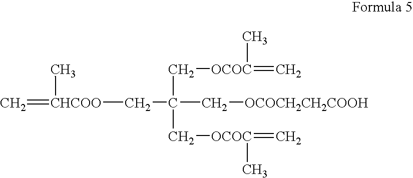

In one embodiment, the carboxyl group-containing polyfunctional monomer is in an amount from about 1 to about 100 parts by weight, optionally from about 25 to about 50 parts by weight based on 100 parts by weight of the photopolymerizable acrylic monomer. The use of the carboxyl group-containing polyfunctional monomer can improve the developability with alkaline solutions and the adhesion between glass substrates and photosensitive resin films.

The solvent may be selected from, for example, ethylene glycol acetate, ethylcellosolve, propylene glycol methyl ether acetate, ethyl lactate, polyethylene glycol, cyclohexanone, propylene glycol methyl ether, and a mixture of two or more of the foregoing.

The amount of the solvent added is not specifically limited since it varies depending on the kind of the photosensitive resin composition. In one embodiment, the solvent is added in such an amount that the resin solution has a viscosity suitable for application to a substrate. The solvent may be in an amount from about 20 to about 80 parts by weight based on 100 parts by weight of the photosensitive resin composition.

Optionally, the composition may further include at least one additive selected from dispersants, surfactants, antioxidants and stabilizers.

In one embodiment, a dispersant for dispersing the pigment in the composition is used. The dispersant may be added to the inside or outside of the pigment in such a manner that the surface of the pigment is pre-treated.

The dispersant may be of non-ionic, anionic or cationic type. Examples of suitable dispersants include, but are not limited to, polyalkylene glycols and esters thereof, polyoxyalkylene polyhydric alcohol ester alkylene oxide adducts, alcohol alkylene oxide adducts, sulfonic acid esters and salts, carboxylic acid esters and salts, alkylamide alkylene oxide adducts, and alkylamines. These dispersants can be added alone or in combination thereof. The dispersant may be in an amount from about 0.1 to about 10 parts by weight based on one part by weight of the pigment.

### Display Devices

One aspect of the invention provides a display device. In one embodiment, the display device includes a substantially transparent substrate, a color layer, and a black matrix interposed between the substrate and the color layer. The black matrix includes a black layer formed of the photosensitive resin composition described above. The black matrix serves to at least partially block ambient light to enhance the contrast of the display device. Examples of the display device include, but are not limited to, a liquid crystal display (LCD), a plasma display panel (PDP), a field emission display (FED), and an organic light emitting display (OLED).

In one embodiment, the photosensitive resin composition described above can be used in forming a black matrix for color filters of a liquid crystal display. The process is described below.

First, the photosensitive resin composition described above is applied to a thickness of about 0.5 to about 10 μm to a glass substrate by a suitable coating technique, such as spin coating, roll coating or spray coating.

Subsequently, the coated substrate is irradiated with actinic rays to form a pattern necessary for color filters. The irradiation is performed by UV radiation in a wavelength range of about 190 to about 450 nm, optionally about 200 to about 400 nm. E-beam and X rays can be used. After the irradiation, the coating layer is treated with a developing solution to dissolve unexposed portions, completing the formation of a final pattern for filters. This procedure is repeatedly carried out according to the intended number of colors to produce color filters having desired patterns. The imaging pattern formed after the development can be heated and cured by irradiation with actinic rays to improve the physical properties, such as crack resistance and solvent resistance, of the black matrix. Further, the black matrix produced using the photosensitive resin composition described above is applied to color filters of a liquid crystal display. The black matrix may be in the form of a film. The black matrix may have a shape of matrix or stripe.

A better understanding of the invention may be obtained through the following examples and comparative examples which are set forth to illustrate, but are not to be construed as the limit of the invention.

### EXAMPLES

Photosensitive resin compositions were prepared using the following components:

| | |
|---|---|
| *Binder resin (cardo resin) | |
| (A) 9,9′-Bis(4-hydroxyphenyl)fluorene | 10 g |
| (B) Epichlorohydrin | |
| (C) Acrylic acid | |
| [(A):(B):(C) = 1:2:2 (molar ratio)] | |
| Molecular weight (Mw) = 4,000 | |
| *Photopolymerizable acrylic monomer | |
| Dipentaerythritol triacrylate | 5 g |
| *Photopolymerization initiator | |
| Igacure 369 (available from Ciba-Geigy, Japan) | 0.7 g |
| STR-A (available from Respe, Japan) | 1.3 g |
| *Pigment | |
| BK9599 (Black pigment available from Tokushiki Co., Ltd., | 25 g |
| Chiba, Japan) | |
| *Solvent | |
| Propylene glycol monomethyl ether | 46 g |
| Cyclohexanone | 10 g |
| *Carboxyl group-containing polyfunctional monomer | |
| TO-1382 (available from Toagosei, Japan) | 2 g |

### Example 1

A solution of the photopolymerization initiator in the solvent was stirred at room temperature for 2 hours. Then, the binder resin and the photopolymerizable acrylic monomer were added thereto. The reactants were stirred at room temperature for 2 hours. To the reactants were added the pigment, the carboxyl group-containing polyfunctional monomer, and other additives. The mixture was stirred at room temperature for one hour. The mixture was filtered three times to remove impurities to prepare a photosensitive resin composition. The optical density, developability, heat resistance, chemical resistance, adhesive properties and development margin of the photosensitive resin composition were measured in accordance with the following procedures. The results are shown in Tables 1 and 2 below.

### Example 2

A photosensitive resin composition was prepared in the same manner as in Example 1, except that 5 g of the carboxyl group-containing polyfunctional monomer (TO1382 available from Toagosei, Japan) was used. The physical properties of the composition were evaluated, and the results are shown in Tables 1 and 2.

### Comparative Example 1

A photosensitive resin composition was prepared in the same manner as in Example 1, except that an acrylic binder resin (Benzyl methacrylate/Methacrylic acid (BzMA/MAc)=7/3, Mw=15,000) was used as a binder resin. The physical properties of the composition were evaluated, and the results are shown in Tables 1 and 2.

### Comparative Example 2

A photosensitive resin composition was prepared in the same manner as in Example 1, except that the carboxyl group-containing polyfunctional monomer was not added. The physical properties of the composition were evaluated, and the results are shown in Tables 1 and 2.

TABLE 1

| | Optical | Develop- | Heat | Chemical | Adhesive |
|---|---|---|---|---|---|
| | density | ability | resistance | resistance | properties |
| Example 1 | ◯ | ◯ | ◯ | ◯ | ◯ |
| Example 2 | ◯ | ◯ | ◯ | ◯ | ◯ |
| Comparative | ◯ | X | Δ | X | X |
| Example 1 | | | | | |
| Comparative | ◯ | X | ◯ | ◯ | Δ |
| Example 2 | | | | | |

TABLE 2

| | Development margin | | |
|---|---|---|---|
| | (Minimum size of | | |
| | remaining patterns: | | |
| | 8, 10, 20, 30, 50 μm) | | |
| | 70 sec. | 100 sec. | 130 sec. |
| Example 1 | 8 | 8 | 8 |
| Example 2 | 8 | 8 | 10 |
| Comparative | 30 | 50 | 50 |
| Example 1 | | | |
| Comparative | 10 | 20 | 30 |
| Example 2 | | | |

### Evaluation of Physical Properties

Evaluation of Optical Density

Each of the photosensitive resin compositions was applied to a thickness of 1.2 μm to a glass substrate (thickness: 1 mm), and dried in a hot-air circulating furnace at 80° C. for one minute to obtain a coating film. The film was cooled to room temperature and dried in a hot-air circulating furnace at 230° C. for 30 minutes. The optical density of the dried film was measured using a 310TR optical density meter (available from X-Rite).

Criteria for Evaluation

O: Optical density ≧3.5

Δ: Optical density 2.5-3.5

X: Optical density ≦2.5

Evaluation of Developability

Each of the photosensitive resin compositions was applied to a thickness of 1-2 μm to a chromium-coated glass substrate (thickness: 1 mm), and dried at a constant temperature (60° C.) for a given time (1 min.) on a hot plate to obtain a coating film. Subsequently, photomasks having mask sizes of 8, 10, 20, 30 and 50 μm were placed on the film, and then the film was irradiated using a high-pressure mercury lamp at 365 nm. The exposed film was developed using a 1% aqueous KOH solution at 30° C. At this time, dissolution of unexposed portions was observed.

Criteria for Evaluation

O: Unexposed portions were completely dissolved

Δ: Unexposed portions were split, but gradually dissolved

X: Unexposed portions were split and not dissolved at all

Evaluation of Heat Resistance

Each of the photosensitive resin compositions was applied to a thickness of 1-2 μm to a glass substrate (thickness: 1 mm), and dried in a hot-air circulating furnace at 80° C. for one minute. The coated substrate was irradiated using an ultrahigh-pressure mercury lamp at 365 nm. Subsequently, the exposed substrate was dried in a hot-air circulating furnace at 230° C. for 30 minutes to obtain coating films. Some of the films were again heated in a hot-air circulating furnace at 25° C. for one minute. The difference in optical density (ΔOD) between the films before and after the heating was measured to evaluate the heat resistance of the films.

Criteria for Evaluation

O: Difference of optical density (ΔOD) ≦0.5

Δ: Difference of optical density (ΔOD) 0.5-1

X: Difference of optical density (ΔOD) ≧1

Evaluation of Chemical Resistance

Each of the photosensitive resin compositions was applied to a thickness of 1-2 μm to a glass substrate (thickness: 1 mm), and dried in a hot-air circulating furnace at 80° C. for one minute. The coated substrate was irradiated using an ultrahigh-pressure mercury lamp at 365 nm, developed with a 1% aqueous KOH solution at ambient pressure at 230° C. for 30 minutes, and dried in a hot-air circulating furnace at 230° C. for 30 minutes to obtain coating films. Some of the films were immersed in 5% HCl, NaOH, xylene, NMP, IPA and acetone solutions for 30 minutes. The difference in optical density (ΔOD) between the films before and after the immersion was measured to evaluate the heat resistance of the films.

Criteria for Evaluation

O: Difference of optical density (ΔOD) ≦0.5

Δ: Difference of optical density (ΔOD) 0.5-1

X: Difference of optical density (ΔOD) ≧1

Evaluation of Adhesive Properties

Each of the photosensitive resin compositions was applied to a thickness of 1-2 μm to a glass substrate (thickness: 1 mm), and dried in a hot-air circulating furnace at 80° C. for one minute to obtain a coating film. The coating film was irradiated using an ultrahigh-pressure mercury lamp at 365 nm with an exposure energy of 300 mj. After the exposed film was heated in a hot-air circulating furnace at 230° C. for 30 minutes, it was divided into 100 blocks (each having an area of 1 mm×1 mm) using a razor blade. An adhesive tape was attached to the blocks and suddenly detached therefrom. The peeling state was visually observed.

Criteria for Evaluation

O: 100/100 (Peeled blocks/Total blocks)—No peeling was observed

Δ: 80/100-99/100

X: 0/100-79/100

Evaluation of Development Margin

Each of the photosensitive resin compositions was applied to a thickness of 1-2 μm to a chromium-coated glass substrate (thickness: 1 mm), and dried at a constant temperature (60° C.) for a given time (1 min.) on a hot plate to obtain a coating film. Subsequently, photomasks having mask sizes of 8, 10, 20, 30 and 50 μm were placed on the film, and then the film was irradiated using a high-pressure mercury lamp at 365 nm. The exposed film was developed using a 1% aqueous KOH solution at ambient pressure at 30° C. for a predetermined time (70, 100 and 130 sec.). The size of remaining patterns was measured to evaluate the development margin of the film.

As can be seen from the data shown in Table 1, the photosensitive resin compositions prepared in Examples 1 and 2 exhibit better physical properties, including optical density, developability, heat resistance, chemical resistance and adhesive properties, than those prepared in Comparative Examples 1 and 2. Particularly, the developability and adhesive properties of the photosensitive resin compositions prepared in Examples 1 and 2 are by far superior to those of the photosensitive resin compositions prepared in Comparative Examples 1 and 2.

As is evident from the results of Table 2, the photosensitive resin compositions prepared in Examples 1 and 2 exhibit superior development margin, compared to those prepared in Comparative Examples 1 and 2.

As apparent from the above description, the embodiments described above provide a photosensitive resin composition suitable for the production of a black matrix in which a carboxyl group-containing polyfunctional monomer is used to improve the physical properties, such as developability, adhesion to glass substrates, heat resistance, chemical resistance and development margin, of the composition. In addition, the embodiments provide a light-shielding black matrix for use in a liquid crystal display using the photosensitive resin composition.

Since the photosensitive resin composition is cured by light irradiation and can be developed with an aqueous alkaline solution (i.e. alkali development type), it causes no environmental pollution and leaves no undissolved material in radiation-unexposed portions.

Although the embodiments have been disclosed for illustrative purposes, those skilled in the art will appreciate that various modifications, additions and substitutions are possible, without departing from the scope and spirit of the invention as disclosed in the accompanying claims.

What is claimed is:

1. A composition for making a black strip or matrix in a display device, the composition comprising:
a black pigment; and
a polymerizable compound represented by Formula 1: 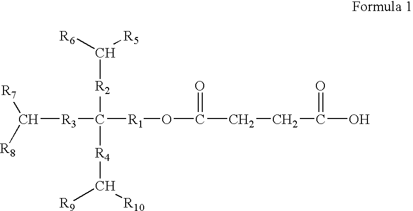
wherein R1 is a saturated or unsaturated, substituted or unsubstituted, C₁-C₂₀ alkyl, the substituted C₁-C₂₀ alkyl being substituted with one or more halogens;
wherein each of R2, R3, and R4 is independently no atom or a saturated or unsaturated, substituted or unsubstituted C₁-C₁₉ alkyl, the substituted C₁-C₁₉ alkyl being substituted with one or more halogens;
wherein each of R5-R10 is independently hydrogen or a substituent group represented by Formula 1-1: 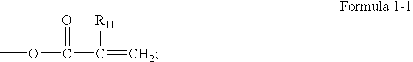
wherein R11 is hydrogen or methyl; and
wherein the total number of the substituent groups represented by Formula 1-1 in the polymerizable compound is between 3 and 6.

2. The composition of claim 1, wherein the polymerizable compound comprises 3 to 6 of reactive ethylenyl groups which are cross-linkable to another polymerizable compound or polymer.

3. The composition of claim 1, wherein each of R2, R3, and R4 is independently straight alkyl.

4. The composition of claim 1, wherein the polymerizable compound is represented by Formula 4 or Formula 5:

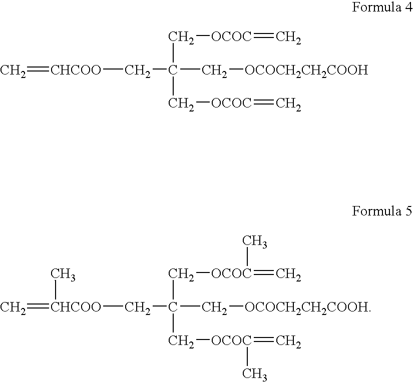

5. The composition of claim 1, further comprising a cardo resin.

6. The composition of claim 5, wherein the cardo resin comprises a polymer of at least two or more selected from the group consisting of compounds represented by Formulas 2-1, 2-2 and 2-3: 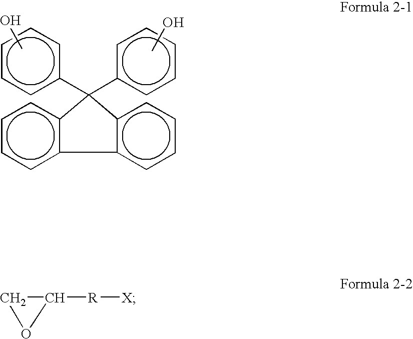
and
CH₂═CRCOOH Formula 2-3
wherein R is hydrogen, substituted or unsubstituted C₁-C₁₀ alkyl, substituted or unsubstituted allyl, substituted or unsubstituted phenyl, substituted or unsubstituted benzyl, or substituted or unsubstituted C₁-C₈ epoxy, and
wherein X is halogen.

7. The composition of claim 1, further comprising a photo-polymerizable acrylic monomer.

8. The composition of claim 7, wherein the polymerizable compound is in an amount from about 25 to about 50 parts by weight based on 100 parts by weight of the acrylic monomer.

9. The composition of claim 1, further comprising a photo-polymerization initiator.

10. The composition of claim 1, wherein the composition is in a form of film.

11. The composition of claim 10, wherein the film comprises a form of matrix or stripe.

12. An electronic device comprising a display comprising a black layer, the black layer comprising:
a black pigment; and
a polymer of a polymerizable compound represented by Formula 1: 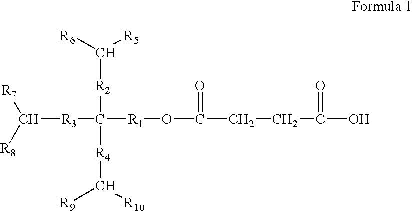
wherein R1 is a saturated or unsaturated, substituted or unsubstituted, C₁-C₂₀ alkyl, the substituted C₁-C₂₀ alkyl being substituted with one or more halogens;
wherein each of R2, R3, and R4 is independently no atom or a saturated or unsaturated, substituted or unsubstituted C₁-C₁₉ alkyl, the substituted C₁-C₁₉ alkyl being substituted with one or more halogens;
wherein each of R5-R10 is independently hydrogen or a substituent group represented by Formula 1-1: 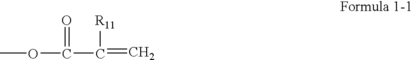
wherein R11 is hydrogen or methyl; and
wherein the total number of the substituent groups represented by Formula 1-1 in the polymerizable compound is between 3 and 6.

13. The device of claim 12, wherein the polymerizable compound is represented by Formula 4 or Formula 5:

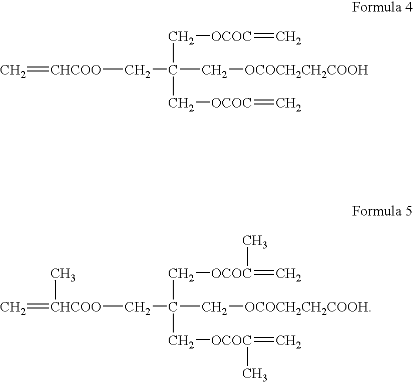

14. The device of claim 12, wherein the black layer further comprises a cardo resin.

15. The device of claim 14, wherein at least a portion of the polymer of the polymerizable compound is cross-linked to the cardo resin.

16. The device of claim 12, wherein the display device comprises a substantially transparent substrate, a color layer, and a black matrix interposed between the substrate and the color layer, and wherein the black matrix comprises the black layer.

17. The device of claim 12, wherein the display device comprises a liquid crystal display (LCD) device.

18. A method of making an electronic device comprising a display, the method comprising:
forming a layer of the composition of claim 1 on a partially fabricated electronic device;
selectively irradiating light onto the layer of the composition; and
treating the layer of the composition with a developing solution.

19. The method of claim 18, wherein the light comprises UV or X-ray.

20. An electronic device made by the method of claim 18.
